(19) United States
(12) Patent Application Publication
(10) Pub. No.: US 2011/0060966 A1
(43) Pub. Date: Mar. 10, 2011

(54) DATA PROGRAMMING METHOD AND SYSTEM THEREOF

(75) Inventor: Shu-Mei Huang, Hsinchu County (TW)

(73) Assignee: ROBUSTFLASH TECHNOLOGIES LTD., Hsinchu County (TW)

(21) Appl. No.: 12/603,585

(22) Filed: Oct. 22, 2009

(30) Foreign Application Priority Data
Sep. 10, 2009 (TW) 98130603

(51) Int. Cl. H03M 13/05; G06F 12/00; G06F 11/10

(52) U.S. Cl. 714/763; 711/154; 711/E12.001; 714/E11.034

(57) ABSTRACT

A data programming method and a system thereof are provided to program an original data into a memory. In the method, the original data complying with a first data arrangement rule is converted into an intermediate data complying with a second data arrangement rule, wherein the second arrangement rule corresponds to a type of the memory. Next, the intermediate data is analyzed to obtain at least one failure area which causes program disturb, and the content of the at least one failure area is replaced by a corresponding adjustment code. The replaced intermediate data is encoded, and a corresponding encoding information is generated. After the encoded intermediate data and the encoding information are both converted into a non-failure data complying with the first data arrangement rule, the non-failure data is programmed into the memory.

### CROSS-REFERENCE TO RELATED APPLICATION

This application claims the priority benefit of Taiwan application serial no. 98130603, filed on Sep. 10, 2009. The entirety of the above-mentioned patent application is hereby incorporated by reference herein and made a part of specification.

### BACKGROUND OF THE INVENTION

1. Field of the Invention

The invention relates to a memory device, and more particularly to a data programming method of a memory device for avoiding program disturb and a system thereof.

2. Description of Related Art

In the semiconductor industry, the memory device is a product having the market potential and the perspective. Generally, a specific read/write interface is necessary for the memory device to communicate with the host or other external apparatuses. Furthermore, with the progress in science and technology, the capacity inside the memory device becomes more and more, and even reaches to several megabytes. However, the read/write interface simply accesses the data in units of byte or word. As a result, when the data is necessarily programmed into the memory, the accessing size of the data is limited to the read/write interface.

In such a configuration, the arrangement of the data inside the memory device is different from that of the external original data. The neighboring two bits in the original data may no longer be adjacent to each other after being programmed into the memory. Accordingly, for the external original data, the arrangement thereof inside the memory device can not be deduced directly.

With the memory device gradually developed as a large memory array, when being read, written, or erased, the neighboring data inside the memory device easily interfere with each other due to the excessive voltage or other physical element, thereby resulting in the scrambled or missing data. Currently, the solution for reducing the degree of the interference is usually improving something inside the memory device. However, for the random data to be programmed, the solution has not been provided.

### SUMMARY OF THE INVENTION

Accordingly, an embodiment of the invention provides a data programming method for a memory. The data is converted before being programmed, thereby reducing the occurrence of the scrambled or missing data in the memory.

An embodiment of the invention provides a data programming system. The data programming system prevents the data which easily interferes other data from being programmed into the memory.

An embodiment of the invention provides a data programming method configured to program an original data complying with a first arrangement rule into a memory. In this method, the original data is converted to an intermediate data according to a second arrangement rule. Herein, the second arrangement rule corresponds to a type of the memory. Next, the intermediate data is analyzed to obtain at least one failure area causing a program disturb, and a content of the at least one failure area is replaced by a corresponding adjustment code. Thereafter, the replaced intermediate data is encoded, and a corresponding encoding information is generated. After the encoded intermediate data and the encoding information are converted to a non-failure data complying with the first data arrangement rule, the non-failure data is programmed into the memory.

In an embodiment of the invention, the step of converting the original data to the intermediate data according to the second arrangement rule includes a step of rearranging each bit of the original data according to the second arrangement rule to generate the intermediate data.

In an embodiment of the invention, the step of analyzing the intermediate data to obtain the at least one failure area includes following steps. First of all, a plurality of data arrangement formats are provided, wherein each of the data arrangement formats corresponds to a failure peak value. Next, locations of the data arrangement formats appearing in the intermediate data are mapped to the corresponding failure peak values. After the mapped intermediate data is compared with a failure peak threshold, areas with the failure peak values higher than the failure peak threshold are determined as the failure areas.

In an embodiment of the invention, the step of replacing the content of the at least one failure area by the corresponding adjustment code includes a step of replacing the content of the at least one failure area by a corresponding predetermined adjustment code.

In an embodiment of the invention, the step of replacing the content of the at least one failure area by the corresponding adjustment code includes a step of executing an inverse process on the content of the at least one failure area to generate a corresponding replacement value. Thereafter, the content of the at least one failure area is replaced by the corresponding replacement value.

In an embodiment of the invention, the encoding information includes an encoding algorithm and a corresponding relationship between the replaced failure area and the adjustment code.

In an embodiment of the invention, the step of converting the encoded intermediate data and the encoding information to the non-failure data complying with the first data arrangement rule includes following steps. First of all, the encoded intermediate data and the encoding information are combined as an integrated data complying with the second data arrangement rule. Next, each bit of the integrated data is rearranged according to the first arrangement rule to generate the non-failure data.

In an embodiment of the invention, the original data includes an error correcting code (ECC) encoding information or an ECC decoding information.

In an embodiment of the invention, the original data is a digital data or an analog data.

In an embodiment of the invention, the memory is a read only memory (ROM), a random access memory (RAM), an erasable programmable read only memory (EPROM), an electrically-erasable programmable read only memory (EEPROM), a flash memory, or a programmable random access memory (PRAM).

Another embodiment of the invention provides a data programming system including a memory, a read/write interface, and a data converting unit. The read/write interface is configured to receive an original data complying with a first arrangement rule. The data converting unit is coupled between the memory and the read/write interface, and converts the original data to an intermediate data according to a second arrangement rule, wherein the second arrangement rule corresponds to a type of the memory. Next, the data converting unit analyzes the intermediate data to obtain at least one failure area in the intermediate data causing a program disturb, and the data converting unit replaces a content of the at least one failure area by a corresponding adjustment code. Thereafter, the data converting unit encodes the replaced intermediate data, and generates a corresponding encoding information. Afterwards, the data converting unit converts the encoded intermediate data and the encoding information to a non-failure data complying with the first data arrangement rule. Finally, the data converting unit programs the non-failure data into the memory.

In an embodiment of the invention, the data converting unit rearranges each bit of the original data according to the second arrangement rule to generate the intermediate data.

In an embodiment of the invention, the data converting unit obtains a plurality of data arrangement formats, wherein each of the data arrangement formats corresponds to a failure peak value. First of all, the data converting unit maps locations of the data arrangement formats appearing in the intermediate data to the corresponding failure peak values. Next, the data converting unit compares the mapped intermediate data with a failure peak threshold. Finally, the data converting unit determines areas with the failure peak values higher than the failure peak threshold as the failure areas.

In an embodiment of the invention, the data converting unit replaces the content of the at least one failure area by a corresponding predetermined adjustment code.

In an embodiment of the invention, the data converting unit executes an inverse process on the content of the at least one failure area to generate a corresponding replacement value, and the data converting unit replaces the content of the at least one failure area by the corresponding replacement value.

In an embodiment of the invention, the encoding information includes an encoding algorithm and a corresponding relationship between the replaced failure area and the adjustment code.

In an embodiment of the invention, the data converting unit combines the encoded intermediate data and the encoding information as an integrated data complying with the second data arrangement rule, and the data converting unit rearranges each bit of the integrated data according to the first arrangement rule to generate the non-failure data.

In an embodiment of the invention, the original data includes an ECC encoding information or an ECC decoding information.

In an embodiment of the invention, the original data is a digital data or an analog data.

In an embodiment of the invention, the memory is a ROM, a RAM, an EPROM, an EEPROM, a flash memory, or a PRAM.

In view of the above, in the embodiments of the invention, the arrangement of the data is changed according to the type of the memory before the data is programmed. Also, the failure areas therein causing a program disturb are found, thereby marking and converting the data. As a result, the possibility of programming the data which easily interferes other data into the memory is reduced, thereby ensuring the reliability after the data has been programmed into the memory.

To make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flowchart of a data programming method according to an embodiment of the invention.

FIG. 2 illustrates the original data and the intermediate data according to an embodiment of the present invention.

FIG. 3 is a flowchart of obtaining the failure area according to an embodiment of the invention.

FIG. 4 is a block diagram of a data programming system according to an embodiment of the present invention.

### DESCRIPTION OF EMBODIMENTS

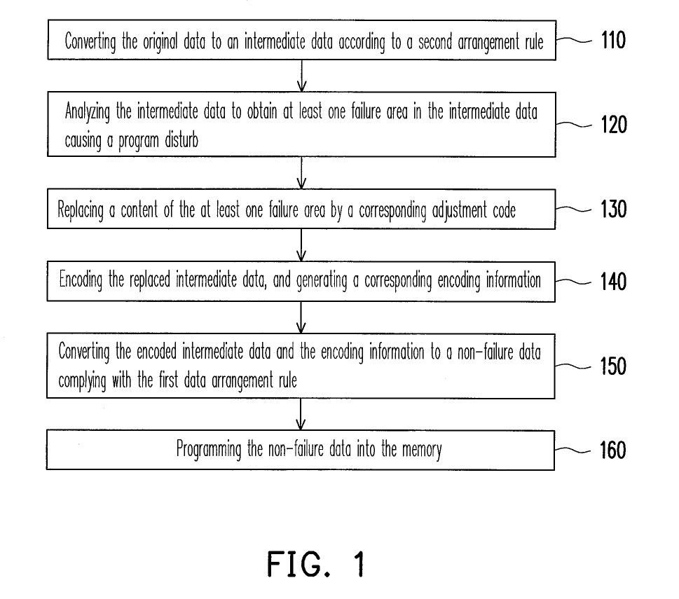

FIG. 1 is a flowchart of a data programming method according to an embodiment of the invention, wherein FIG. 1 illustrates steps in data programming method configured to program an original data complying with a first arrangement rule into a memory. Herein, the original data is a digital data or an analog data, and the format of the original data is not limited thereto. Besides a general data, the content of the original data further includes an error correcting code (ECC) encoding information or an ECC decoding information, for example. Furthermore, the memory may be a read only memory (ROM), a random access memory (RAM), an erasable programmable read only memory (EPROM), an electrically-erasable programmable read only memory (EEPROM), a flash memory, or a programmable random access memory (PRAM).

After the original data to be programmed into the memory is received, the original data is converted to an intermediate data according to a second arrangement rule, as shown in step 110. Herein, the second arrangement rule corresponds to a type of the memory. Moreover, the data inside the different type of the memory is arranged in different arrangement. Accordingly, in step 110, the second arrangement rule is obtained according to the type of the memory, and each bit of the original data is rearranged according to the second arrangement rule, thereby converting the original data complying with the first arrangement rule to the intermediate data complying with the second arrangement rule. Furthermore, even for the same original data, if the original data is programmed into the different type of the memory, the converted intermediate data is also different in step 110.

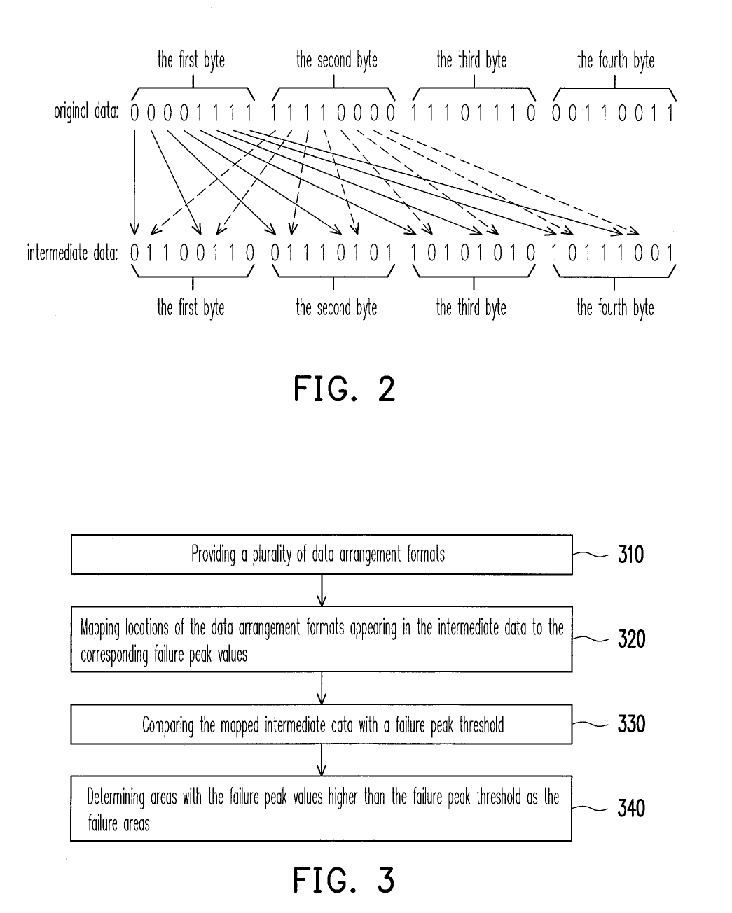

An exemplary embodiment for converting the original data to the intermediate data according to the second arrangement rule will be described as follows. As shown in FIG. 2, the bit 0 locating at the first bit in the first byte of the original data will be located at the first bit in the first byte of the intermediate data after being rearranged. The bit 0 locating at the second bit in the first byte of the original data will be located at the fifth bit in the first byte of the intermediate data after being rearranged. The bit 1 locating at the first bit in the second byte of the original data will be located at the second bit in the first byte of the intermediate data after being rearranged, the bit 1 locating at the second bit in the second byte of the original data will be located at the sixth bit in the first byte of the intermediate data after being rearranged, and so on.

As shown in FIG. 2, a new arrangement of the bits in the intermediate data is obtained after each bit of the original data has been rearranged. However, it should be noted that, the rearrangement of the original data is simply an exemplary embodiment for description. For the different type of the memory, the bits have different arrangement inside the memory. Accordingly, the method of generating the converted intermediate data is different. Besides, the second arrangement rule means a reference rule for rearranging the bits. Accordingly, any rule capable of representing the relationship between the locations of the bits can be used for the second arrangement rule.

Next, referring to FIG. 1, in step 120, the intermediate data is analyzed to obtain at least one failure area causing a program disturb in the intermediate data. The detail of step 120 will be described as follows in FIG. 3. First of all, a plurality of data arrangement formats are provided, wherein each of the data arrangement formats corresponds to a failure peak value. Herein the data arrangement format is related to the type of the original data. If the original data is a digital data, the data arrangement format is an arrangement including the bits 0 and 1. For example, such a data arrangement format of the sequential four bits 1, i.e. 1111, has the highest failure peak value, e.g. 10, and such a data arrangement format of the sequential three bits 1, i.e. 111, has the middle failure peak value, e.g. 5. Similarly, such a data arrangement format of the single bit 1, i.e. 1, has the lowest failure peak value, e.g. 1. The type of the data arrangement format and the failure peak value corresponding to each of the data arrangement formats may be a result obtained by gathering statistics from a larger number of data previously programmed into the memory, and it does not limit the invention.

Next, in step 320, locations of the data arrangement formats appearing in the intermediate data are respectively mapped to the corresponding failure peak values. That is, in the intermediate data, all of the data complying with the locations of the data arrangement formats are mapped to the failure peak values corresponding to the data arrangement format. If the original data is a digital data, the intermediate data is converted from the digital data format to the analog data format. Next, the mapped intermediate data is compared with a failure peak threshold, as shown in step 330. Finally, in step 340, areas with the failure peak values higher than the failure peak threshold are determined as the failure areas. Through steps shown in FIG. 3, the failure areas can be obtained in the intermediate data.

In the present embodiment, the determined failure areas mean that the combinations of the data in the areas are peak failure data, which easily interfere and destroy the neighboring data in the memory after the data has been programmed thereinto. Accordingly, in order to reduce the degree of the destruction, when all of the failure areas have been obtained, the content of each failure area is respectively replaced by an adjustment code corresponding thereto later, as shown in step 130. During replacing, a corresponding predetermined adjustment code is used to replace the content of each failure area. For example, when the content of the failure area is the sequential four bits 1, a kind of the predetermined adjustment code replaces the content, and when the content of the failure area is the sequential three bits 1, another kind of the predetermined adjustment code replaces the content. In another embodiment, an inverse process is respectively executed on the content of each failure area to generate a corresponding replacement value, and next, the content of each failure area is respectively replaced by the corresponding replacement value. The above replacements are simply the exemplary embodiments consistent with the invention, and they do not limit the scope of the invention.

After the failure area easily causing program disturb is replaced by the adjustment code, the replaced intermediate data, including the failure area and the non-failure area, is encoded, and a corresponding encoding information is generated, as shown in step 140. Herein, the encoding information includes a used encoding algorithm and a corresponding relationship between each of the replaced failure area and the adjustment code. In the present embodiment, the used encoding algorithm is not limited during encoding.

Next, in step 150, the encoded intermediate data and the generated encoding information are both converted to a non-failure data complying with the first data arrangement rule. Specifically, in step 150, the encoded intermediate data and the encoding information are first combined as an integrated data complying with the second data arrangement rule. Next, each bit of the integrated data is rearranged according to the first arrangement rule to generate the non-failure data. Finally, in step 160, the non-failure data is programmed into the memory. Up to this point, the flow of the data programming method is finished.

In the above embodiment, once the practical arrangement of the data in the memory is obtained, before the data has been programmed in the memory, the data can be rearranged to find the areas which may cause program disturb, so that the contents of the failure areas are replaced by the predetermined codes. Accordingly, the possibility of destroying the neighboring data is reduced after the data has been programmed in the memory.

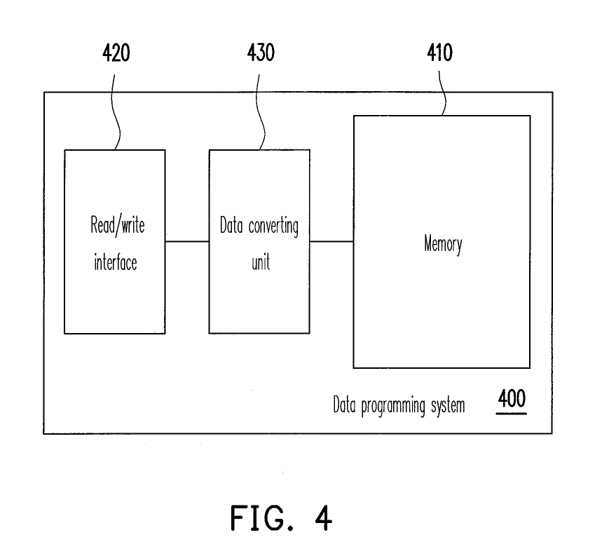

FIG. 4 is a block diagram of a data programming system according to an embodiment of the present invention. Referring to FIG. 4, a data programming system 400 includes a memory 410, a read/write interface 420, and a data converting unit 430. Herein, the memory 410 may be a ROM, a RAM, an EPROM, an EEPROM, a flash memory, or a PRAM, and the invention is not limited thereto. The data programming system 400 communicates with the host, such as the computer system or the server, through the read/write interface 420.

The data converting unit 430 may be hardware, software, or a combination thereof having the capability to execute the operation. When the read/write interface 420 receives the original data transmitted from the host, the data converting unit 430 obtains the corresponding second arrangement rule according to the type of the memory 410, thereby converting the original data complying with the first arrangement rule to the intermediate data complying with the second arrangement rule. Next, the intermediate data is analyzed to find the failure area causing program disturb, and the content of each failure area is respectively replaced by the corresponding adjustment code. After finishing replacing, the data converting unit 430 encodes the replaced intermediate data, and converts both of the generated encoding information and the encoded intermediate data to the non-failure data complying with the first data arrangement rule. Finally, the data converting unit 430 replaces the original data by the non-failure data, and programs the non-failure data into the memory 410.

Through the data converting unit 430, the occurrence of the scrambled or missing data can be reduced when the data is programmed into the memory. It is similar to or the same as the above embodiment that the data converting unit 430 converts the original data to the intermediate data, analyzes, replaces, and encodes the intermediate data, and generates the non-failure data, and it is not described herein.

To sum up, in the data programming method and system of the embodiments consistent with the invention, the data is converted before being programmed into the memory, thereby finding the failure areas easily interfering the neighboring data in the memory. Also, the data in the failure areas is replaced by the data with the lower failure peak value, and next, the processed data is programmed into the memory. Accordingly, it is ensured that the programmed data is not easy to interfere the neighboring data, thereby enhancing the reliability of programming the data into the memory.

Although the invention has been described with reference to the above embodiments, it is apparent to one of the ordinary skill in the art that modifications to the described embodiments may be made without departing from the spirit of the invention. Accordingly, the scope of the invention will be defined by the attached claims not by the above detailed descriptions.

What is claimed is:

1. A data programming method, configured to program an original data into a memory, wherein the original data complies with a first arrangement rule, the data programming method comprising:
converting the original data to an intermediate data according to a second arrangement rule, wherein the second arrangement rule corresponds to a type of the memory;
analyzing the intermediate data to obtain at least one failure area in the intermediate data causing a program disturb;
replacing a content of the at least one failure area by a corresponding adjustment code;
encoding the replaced intermediate data, and generating a corresponding encoding information;
converting the encoded intermediate data and the encoding information to a non-failure data complying with the first data arrangement rule; and
programming the non-failure data into the memory.

2. The data programming method as claimed in claim 1, wherein the step of converting the original data to the intermediate data according to the second arrangement rule comprises:
rearranging each bit of the original data according to the second arrangement rule to generate the intermediate data.

3. The data programming method as claimed in claim 1, wherein the step of analyzing the intermediate data to obtain the at least one failure area comprises:
providing a plurality of data arrangement formats, wherein each of the data arrangement formats corresponds to a failure peak value;
mapping locations of the data arrangement formats appearing in the intermediate data to the corresponding failure peak values;
comparing the mapped intermediate data with a failure peak threshold; and
determining areas with the failure peak values higher than the failure peak threshold as the failure areas.

4. The data programming method as claimed in claim 1, wherein the step of replacing the content of the at least one failure area by the corresponding adjustment code comprises:
replacing the content of the at least one failure area by a corresponding predetermined adjustment code.

5. The data programming method as claimed in claim 1, wherein the step of replacing the content of the at least one failure area by the corresponding adjustment code comprises:
executing an inverse process on the content of the at least one failure area to generate a corresponding replacement value; and
replacing the content of the at least one failure area by the corresponding replacement value.

6. The data programming method as claimed in claim 1, wherein the encoding information comprises an encoding algorithm and a corresponding relationship between the replaced failure area and the adjustment code.

7. The data programming method as claimed in claim 1, wherein the step of converting the encoded intermediate data and the encoding information to the non-failure data complying with the first data arrangement rule comprises:
combining the encoded intermediate data and the encoding information as an integrated data complying with the second data arrangement rule; and
rearranging each bit of the integrated data according to the first arrangement rule to generate the non-failure data.

8. The data programming method as claimed in claim 1, wherein the original data comprises an error correcting code (ECC) encoding information or an ECC decoding information.

9. The data programming method as claimed in claim 1, wherein the original data is a digital data or an analog data.

10. The data programming method as claimed in claim 1, wherein the memory is a read only memory (ROM), a random access memory (RAM), an erasable programmable read only memory (EPROM), an electrically-erasable programmable read only memory (EEPROM), a flash memory, or a programmable random access memory (PRAM).

11. A data programming system, comprising:
a memory;
a read/write interface receiving an original data complying with a first arrangement rule; and
a data converting unit coupled between the memory and the read/write interface, the data converting unit converting the original data to an intermediate data according to a second arrangement rule, wherein the second arrangement rule corresponds to a type of the memory, the data converting unit analyzing the intermediate data to obtain at least one failure area in the intermediate data causing a program disturb, the data converting unit replacing a content of the at least one failure area by a corresponding adjustment code, the data converting unit encoding the replaced intermediate data, and generating a corresponding encoding information, the data converting unit converting the encoded intermediate data and the encoding information to a non-failure data complying with the first data arrangement rule, and the data converting unit programming the non-failure data into the memory.

12. The data programming system as claimed in claim 11, wherein the data converting unit rearranges each bit of the original data according to the second arrangement rule to generate the intermediate data.

13. The data programming system as claimed in claim 11, wherein the data converting unit obtains a plurality of data arrangement formats, wherein each of the data arrangement formats corresponds to a failure peak value, the data converting unit maps locations of the data arrangement formats appearing in the intermediate data to the corresponding failure peak values, the data converting unit compares the mapped intermediate data with a failure peak threshold, and the data converting unit determines areas with the failure peak values higher than the failure peak threshold as the failure areas.

14. The data programming system as claimed in claim 11, wherein the data converting unit replaces the content of the at least one failure area by a corresponding predetermined adjustment code.

15. The data programming system as claimed in claim 11, wherein the data converting unit executes an inverse process on the content of the at least one failure area to generate a corresponding replacement value, and the data converting unit replaces the content of the at least one failure area by the corresponding replacement value.

16. The data programming system as claimed in claim 11, wherein the encoding information comprises an encoding algorithm and a corresponding relationship between the replaced failure area and the adjustment code.

17. The data programming system as claimed in claim 11, wherein the data converting unit combines the encoded intermediate data and the encoding information as an integrated data complying with the second data arrangement rule, and the data converting unit rearranges each bit of the integrated data according to the first arrangement rule to generate the non-failure data.

18. The data programming system as claimed in claim 11, wherein the original data comprises an error correcting code (ECC) encoding information or an ECC decoding information.

19. The data programming system as claimed in claim 11, wherein the original data is a digital data or an analog data.

20. The data programming system as claimed in claim 11, wherein the memory is a read only memory (ROM), a random access memory (RAM), an erasable programmable read only memory (EPROM), an electrically-erasable programmable read only memory (EEPROM), a flash memory, or a programmable random access memory (PRAM).
